(19) United States
(12) Patent Application Publication
(10) Pub. No.: US 2016/0017487 A1
(43) Pub. Date: Jan. 21, 2016

(54) INTEGRATED PRE-CLEAN AND DEPOSITION OF LOW-DAMAGE LAYERS

(71) Applicant: Applied Materials, Inc., Santa Clara, CA (US)

(72) Inventors: Yihong CHEN, San Jose, CA (US); Shaunak MUKHERJEE, Santa Clara, CA (US); Martin Jay SEAMONS, San Jose, CA (US); Kelvin CHAN, San Ramon, CA (US); Abhijit Basu MALLICK, Fremont, CA (US); Bok Hoen KIM, San Jose, CA (US); Jianhua ZHOU, Campbell, CA (US)

(21) Appl. No.: 14/472,311

(22) Filed: Aug. 28, 2014

Related U.S. Application Data
(60) Provisional application No. 62/024,865, filed on Jul. 15, 2014.

(51) Int. Cl. C23C 16/34; C23C 16/50; C23C 16/40; C23C 16/44

(52) U.S. Cl. CPC C23C 16/34; C23C 16/44; C23C 16/50; C23C 16/401

(57) ABSTRACT

A method of processing a substrate includes positioning the substrate within a processing zone of a processing chamber and removing an oxide layer from a surface of the substrate by introducing first radicals into the processing zone. The method further includes, after removing the oxide layer, introducing at least one first precursor gas into the processing zone and depositing at least one dielectric layer onto the surface by exposing the at least one first precursor gas to second radicals. After positioning the substrate within the processing zone, the substrate is not removed from the processing chamber until each of removing the oxide layer and depositing the at least one dielectric layer is performed.

### CROSS-REFERENCE TO RELATED APPLICATIONS

This application claims priority to U.S. Provisional Patent Application Ser. No. 62/024,865, filed on Jul. 15, 2014, which is hereby incorporated herein by reference.

### BACKGROUND

1. Field

Embodiments disclosed herein generally relate to the development of dielectric layers, and more specifically to the development of silicon-containing dielectric layers.

2. Description of the Related Art

The formation of dielectric layers, such as amorphous silicon-containing dielectric layers, under damage-free conditions is desirable for developing next-generation electronic devices. In current techniques, prior to depositing dielectric layers, a substrate may be pre-cleaned in-situ, for example, using a PECVD chamber. The substrate is then transferred to a separate processing chamber, where one or more dielectric layers are deposited. However, plasma generated during conventional pre-clean techniques may cause significant damage to layers that were previously deposited onto the substrate. Further, current techniques for depositing amorphous silicon-containing dielectric layers expose deposited layers to damaging effects, such as charged-particle bombardment and high-energy ultraviolet irradiation. As device components decrease in size, they become increasingly sensitive to such damaging effects.

Therefore, there is a need in the art for forming dielectric layers under low-damage conditions.

### SUMMARY

Embodiments disclosed herein provide a method of processing a substrate. The method includes positioning the substrate within a processing zone of a processing chamber and removing an oxide layer from a surface of the substrate by introducing first radicals into the processing zone. The method further includes, after removing the oxide layer, introducing at least one first precursor gas into the processing zone and depositing at least one dielectric layer onto the surface by exposing the at least one first precursor gas to second radicals. After positioning the substrate within the processing zone, the substrate is not removed from the processing chamber until each of removing the oxide layer and depositing the at least one dielectric layer is performed.

In another embodiment, a method of processing a substrate includes positioning the substrate within a processing zone of a processing chamber and removing an oxide layer from a surface of the substrate by introducing first radicals into the processing zone. The method further includes, after removing the oxide layer, introducing one or more precursor gases into the processing zone and depositing at least one buffer layer onto the surface using the one or more precursor gases. The method further includes, after depositing the at least one buffer layer, introducing a silicon-containing precursor gas into the processing zone and depositing at least one of a SiCN layer and a SiCON layer onto the at least one buffer layer by exposing the silicon-containing precursor gas to second radicals.

In yet another embodiment, a method of processing a substrate includes positioning the substrate within a processing zone of a processing chamber and removing an oxide layer from a surface of the substrate by introducing first radicals into the processing zone. The method further includes, after removing the oxide layer, introducing one or more first precursor gases into the processing zone and depositing at least one buffer layer onto the surface using the one or more first precursor gases. The method further includes, after depositing the at least one buffer layer, introducing one or more second precursor gases into the processing zone and depositing at least one dielectric layer onto the at least one buffer layer by exposing the one or more second precursor gases to second radicals. After positioning the substrate within the processing zone, the substrate is not removed from the processing chamber until each of removing the oxide layer, depositing the at least one buffer layer, and depositing the at least one dielectric layer is performed.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 is a schematic cross-sectional view of one processing chamber suitable for practicing the methods disclosed herein.

FIG. 2 is a schematic cross-sectional view of a substrate having a dielectric capping layer disposed on metal interconnects, according to one embodiment.

FIG. 3 is a flow diagram of a representative method of processing a substrate.

### DETAILED DESCRIPTION

The descriptions of the various embodiments are presented for illustrative purposes and are not intended to be exhaustive or limiting. Many modifications and variations will be apparent to those of ordinary skill in the art without departing from the scope and spirit of the described embodiments. The terminology used herein was chosen to best explain the principles of the embodiments, the practical applications or technical improvements over technologies found in the marketplace, or to enable others of ordinary skill in the art to understand the embodiments disclosed herein.

Embodiments disclosed herein generally provide methods of pre-cleaning a substrate surface, depositing interfacial buffer layer(s), and/or depositing dielectric capping layer(s) in a manner that reduces the likelihood of damage to layers (e.g., low-dielectric films) disposed on the substrate. In some embodiments, the pre-clean step, interfacial buffer layer deposition step, and dielectric capping layer deposition step are performed in a single processing chamber, improving processing throughput. Additionally, substrate contamination that may otherwise occur while transferring the substrate between multiple conventional processing chambers is decreased.

Deposition of the buffer layer(s) and/or dielectric layer(s) may be performed by introducing precursor gases into a processing chamber and thereafter exposing the precursor gases to radicals. The precursor gases may contain silicon. For example, the precursor gases may be one or more organosilicons or tetraalkyl othosilicates. The radicals may include hydrogen radicals, hydroxyl radicals, nitrogen radicals, NH radicals, oxygen radicals, and mixtures thereof. The processing chamber may be, for example, a vacuum sealed chamber containing a radical source or coupled to a radical source. The radical source may be, for example, a remote plasma source or the filament of a hot wire chemical vapor deposition (HW-CVD) chamber. A remote plasma source refers to a region coupled to a processing chamber in which a plasma is generated and that is spatially separated from the region of the processing chamber in which deposition occurs. At least one surface of the processing chamber that contacts the generated radicals may be composed at least in part of materials that are substantially unreactive with the generated radicals in order to maximize the radical flux at the deposition surface.

The methods disclosed herein may offer advantages, such as the following. The use of a radical source may produce growth conditions that are substantially or completely free of layer-damaging effects, such as charged-particle bombardment and high-energy ultraviolet irradiation, which often occur in conventional techniques. Additionally, the generated radicals extract hydrogen from the Si—H, C—H, and N—H bonds of the precursors, allowing for, at a given temperature, the deposition of layers having a lower hydrogen content than conventional techniques. Silicon-containing dielectric layers formed using the methods disclosed herein exhibit, as compared to conventional methods of forming silicon-containing dielectric layers, significantly fewer defects, significantly lower shrinkage, and significantly better etch selectivity, mechanical stability, and thermal stability. Moreover, layers deposited according to the methods disclosed herein offer greater conformality than conventional plasma enhanced chemical vapor deposition (PECVD) techniques. Although not to be limited by theory, it is believed that the improved conformality is related to the inability of plasma, which is limited by the thickness of the plasma sheath, to extend to the bottom of very deep trenches. Radicals can diffuse into and react with precursors in deep trenches much more readily. The aforementioned advantages are illustrative and not limiting. It is not necessary for all embodiments of the invention to have all the advantages of the invention or fulfill all the purposes of the invention.

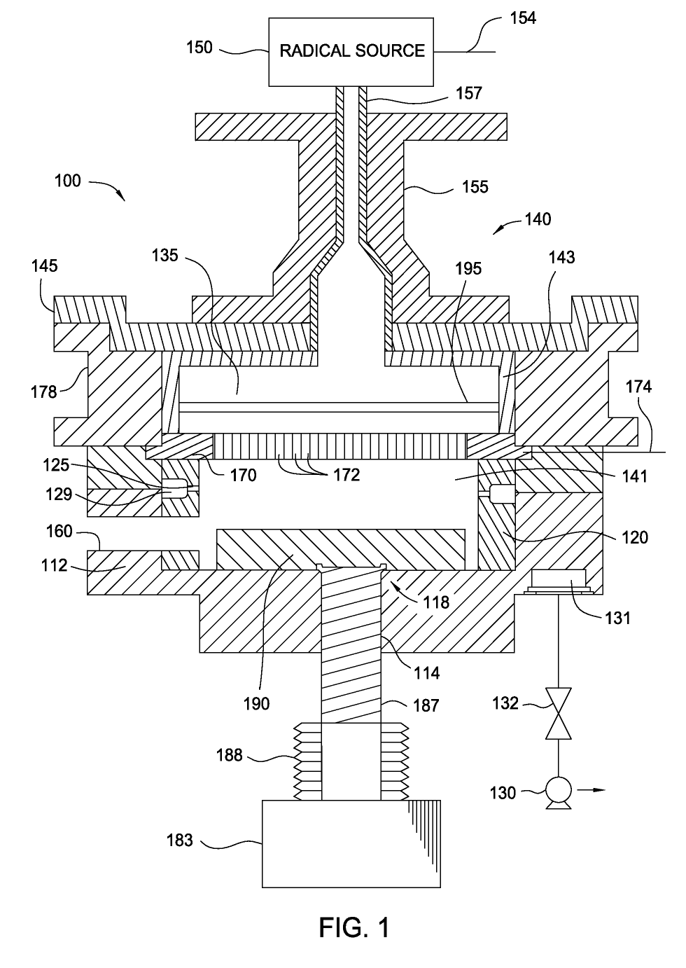

FIG. 1 is a schematic cross-sectional view of one processing chamber suitable for practicing the methods disclosed herein. Many other processing chambers may be used to practice the disclosed embodiments. In one embodiment, the processing chamber 100 includes a chamber body 112, a lid assembly 140, and a support assembly 118. The lid assembly 140 is disposed at an upper end of the chamber body 112, and the support assembly 118 is at least partially disposed within the chamber body 112. The processing chamber 100 is coupled to a radical source 150.

The chamber body 112 includes a slit valve opening 160 formed in a sidewall thereof to provide access to the interior of the processing chamber 100. The slit valve opening 160 is selectively opened and closed to allow access to the interior of the chamber body 112. The chamber body 112 may include a liner 120 that surrounds the support assembly 118. The liner 120 may include one or more apertures 125 and a pumping channel 129 formed therein that is in fluid communication with a vacuum system. The apertures 125 provide a flow path for gases into the pumping channel 129, which provides an egress for the gases within the processing chamber 100.

The vacuum system can include a vacuum pump 130 and a throttle valve 132 to regulate the flow of gases through the processing chamber 100. The vacuum pump 130 is coupled to a vacuum port 131 disposed on the chamber body 112 and therefore, in fluid communication with the pumping channel 129 formed within the liner 120. The apertures 125 allow the pumping channel 129 to be in fluid communication with a processing zone 141 within the chamber body 112. The processing zone 141 is defined by a lower surface of the gas distribution plate 170 and an upper surface of the support assembly 118, and is surrounded by the liner 120.

The support assembly 118 can include a support member 190 to support a substrate (not shown) for processing within the chamber body 112. The substrate may be any standard wafer size, such as, for example, 300 mm. Alternatively, the substrate may be larger than 300 mm. The support member 190 can be coupled to a lift mechanism 183 through a shaft 187 which extends through a centrally-located opening 114 formed in a bottom surface of the chamber body 112. The lift mechanism 183 can be flexibly sealed to the chamber body 112 by a bellows 188 that prevents vacuum leakage from around the shaft 187. The lift mechanism 183 allows the support member 190 to be moved vertically within the chamber body 112 between a process position and a lower, transfer position. The transfer position is slightly below the opening of the slit valve 160 formed in a sidewall of the chamber body 112. During operation, the spacing between the substrate and the gas distribution plate 170 may be minimized in order to maximize radical flux at the substrate surface. For example, the spacing may be between about 100 mil and about 5,000 mil. The support member 190 may also contain a heater (not shown).

The lid assembly 140 includes radical source 150, radical conduit 157, top plate 145, lid rim 178, radical cavity 135, and gas distribution plate 170. Radicals are generated in the radical source 150 and then travel through the radical conduit 157 into the radical cavity 135, where the radicals pass through the gas distribution plate 170 and into the processing zone 141.

Optionally, an ion filter 195 may be disposed in the radical cavity 135. The ion filter 195 removes the ions, electrons, and ultraviolet radiation generated in the plasma in order to maximize radical generation and prevent damage to the deposited layer. Ion filter 195 can also control the number of radicals that pass through. Also optionally, the chamber and chamber component surfaces that contact the radicals may be composed at least in part of a material that is substantially unreactive to radicals. By not consuming the generated radicals, the coating increases the radical flux to the substrate.

The radical source 150 is positioned at the top of the lid assembly 140 and is coupled on one end to radical conduit 157 and on another end to one or more first gas inlets 154 (only one is shown in FIG. 1). One or more process gases, which may include radical-forming gases, may enter the radical source 150 via the first gas inlet(s) 154. The first gas inlet(s) 154 are coupled on another end to one or more upstream gas sources and/or other gas delivery components, such as gas mixers. For example, the first gas inlet(s) 154 may be coupled at the second end to upstream sources of hydrogen, oxygen, H₂O, nitrogen, argon, helium, and/or ammonia that may be used to generate radicals in the radical source 150. Radical source 150 may be coupled directly to radical conduit 157 (as shown) or indirectly through a second radical conduit or other suitable means.

The radical source 150 generates radicals that are used to pre-clean the substrate, deposit one or more buffer layers, and/or deposit one or more dielectric capping layers, such as silicon-containing dielectric capping layers. The radical source 150 may be, for example, a remote plasma source. The remote plasma source may be a capacitively coupled plasma (CCP) source, an inductively coupled plasma (ICP) source, a microwave induced (MW) plasma source, an electron cyclotron resonance (ECR) chamber, or a high density plasma (HDP) chamber. In alternative embodiments that use a different chamber configuration, the radical source may be a filament of a hot wire chemical vapor deposition (HW-CVD) chamber. MW and ECR sources have the highest H₂ disassociation efficiency among common plasma sources. ICP sources have lower disassociation efficiency, which makes deposition of high quality layers more difficult.

Radical conduit 157 is coupled on one end to the radical source 150 and on the other end to the radical cavity 135. Radicals generated in the radical source 150 travel through the radical conduit 157 and into the radical cavity 135. Radical conduit 157 is disposed within and supported by radical conduit support member 155. Radical conduit support member 155 is mounted to top plate 145, and top plate 145 rests on lid rim 178.

Radical conduit 157 may be composed at least in part of a material that is substantially unreactive to radicals. For example, radical conduit 157 may be composed of anodized Al₂O₃; sapphire; AlN; SiO₂; Y₂O₃; MgO; ceramics containing one or more of Al₂O₃, sapphire, AlN, Y₂O₃, MgO; and/or plastics. A representative example of a suitable SiO₂ material is quartz. In the same or other embodiments, radical conduit 157 may include a coating on the surface that contacts the radicals during processing. The coating may also include anodized Al₂O₃; sapphire; AlN; SiO₂; Y₂O₃; MgO; ceramics containing one or more of Al₂O₃, sapphire, AlN, Y₂O₃, MgO; or plastics. If a coating is used, the thickness of the coating may be between about 1 μm and about 1 mm. The coating may be applied using a spray coating process.

Radical cavity 135 is positioned below and coupled to radical conduit 157. Radical cavity 135 is bounded by a ceiling, sidewalls, and gas distribution plate 170. Optionally, the radical cavity 135 may include a liner 143. The liner 143 may cover the sidewalls and/or the ceiling. The surfaces of radical cavity 135 that contact radicals, including the ceiling, sidewalls, surfaces of liner 143, and the top surface of the gas distribution plate 170, may be composed of or coated with a material that is substantially unreactive to radicals. For example, the surfaces may be composed of or coated with anodized Al₂O₃; sapphire; AlN; SiO₂; Y₂O₃; MgO; ceramics containing one or more of Al₂O₃, sapphire, AlN, Y₂O₃, MgO; or plastics. A representative example of a suitable SiO₂ material is quartz. If a coating is used, the thickness of the coating may be between about 1 μm and about 1 mm.

Gas distribution plate 170 is positioned between the radical cavity 135 and the processing zone 141. Gas distribution plate 170 may be a dual channel shower head. Gas distribution plate 170 may include one or more second gas inlets 174 (only one is shown in FIG. 1) that are at least partially formed within gas distribution plate 170. The second gas inlet(s) 174 are in fluid communication with at least some of the plurality of apertures 172 of gas distribution plate 170 at a first end thereof and coupled to one or more gas sources and/or other gas delivery components, such as gas mixers, at a second end thereof. For example, the second gas inlet(s) 174 may be coupled at the second end to one or more sources of precursor gases selected to form dielectric layers in processing zone 141.

Gas distribution plate 170 may include a plurality of apertures 172. Apertures 172 are passageways that distribute the flow of gases therethrough. Apertures 172 can be sized and positioned about gas distribution plate 170 to provide a controlled and even flow distribution to the processing zone 141. The apertures 172 prevent the gas(es) from impinging directly on the substrate surface by slowing and re-directing the velocity profile of the flowing gases, as well as evenly distributing the flow of gas to provide an even distribution of gas across the surface of the substrate. The apertures 172 are configured so that one or more first gases from the first gas inlet(s) 154 and the radicals generated by the radical source 150 can pass through a first set of apertures, and one or more second gases from the second gas inlet(s) 174 can pass through a second set of apertures. Additionally, the apertures 172 may be configured so that the one or more first gases and the generated radicals are not in communication with the one or more second gases while disposed within the apertures 172.

The bottom surface and the surfaces surrounding the apertures 172 of the gas distribution plate 170 may also be coated with a material that is substantially unreactive to radicals. For example, the coating may include anodized Al₂O₃; sapphire; AlN; SiO₂; Y₂O₃; MgO; ceramics containing one or more of Al₂O₃, sapphire, AlN, Y₂O₃, MgO; or plastics. A representative example of a suitable SiO₂ material is quartz. The coating thickness may be between about 1 μm and about 1 mm.

Integrated Processes for Depositing Low-Damage Dielectric Layers

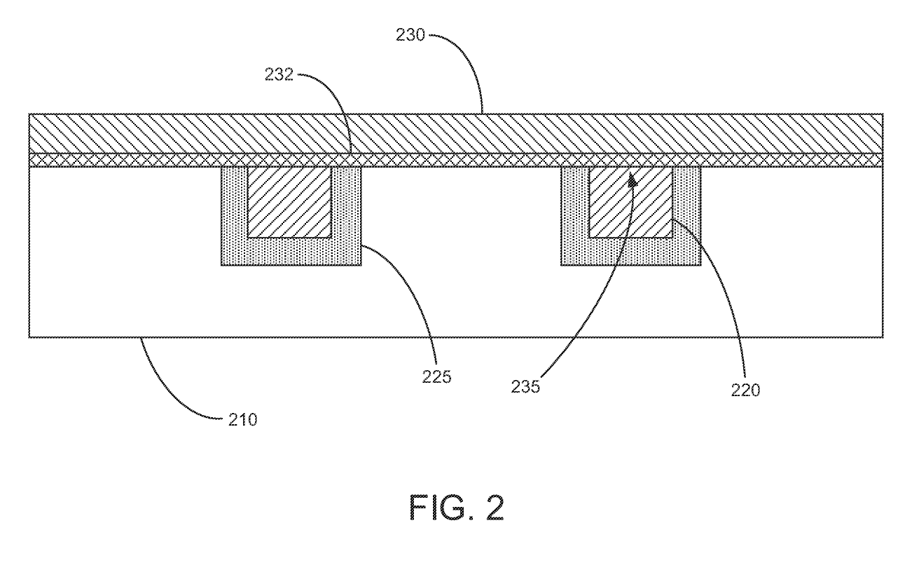

FIG. 2 illustrates a schematic cross-sectional view of a substrate 210 having a dielectric capping layer 230 disposed on metal interconnects 220, according to one embodiment. During back-end-of-line (BEOL) processing, metal interconnects 220 are fabricated to provide electrical connections between various integrated circuit (IC) devices disposed on the substrate 210. In some embodiments, metal interconnects 220 may be formed by embedding copper (Cu) lines into a barrier layer 225, such as a metal-based barrier layer (e.g., TaN/Ta or TiN/Ru) that is disposed along the bottom and/or sidewalls of the Cu lines.

After fabrication of the metal interconnects 220, one or more dielectric capping layers 230 may be formed on the metal interconnects 220. The dielectric capping layer(s) 230 serve as an etch-stopper and/or reduce oxidation of the metal interconnects 220. Additionally, the dielectric capping layers 230 may reduce diffusion of metal(s) that are used to form the metal interconnects 220 through the dielectric/metal interface 235. In general, diffusion of the metal interconnects into the dielectric capping layers 232 may be reduced by improving the adhesion between the dielectric capping layer 230 and the metal interconnects 220.

Adhesion between the dielectric capping layer 230 and the metal interconnects 220 may be improved by performing a pre-clean step and/or a buffer layer formation step prior to depositing the dielectric capping layer(s) 230 on the metal interconnects 220. During the pre-clean step, moisture generated during prior processing step(s) (e.g., chemical-mechanical polishing) may be removed, and/or native oxide layers (e.g., CuOₓ) formed on the metal interconnects 220 may be reduced.

In conventional BEOL processes, the pre-clean step was performed in-situ using a PECVD chamber. However, the plasma that is used in conventional pre-clean techniques may cause significant damage to low-dielectric layers (e.g., SiOC layers) disposed on the substrate. Alternatively, conventional BEOL processes may perform the pre-clean step in a separate chamber, using lower-energy techniques that cannot be performed with conventional PECVD chambers. Consequently, the substrate is transported to one chamber to perform pre-clean and is subsequently transferred to a separate chamber to deposit a capping layer. However, transporting the substrate between multiple chambers reduces throughput and potentially exposes the substrate to contaminants during transfer.

Accordingly, in order to address various deficiencies of conventional processes, in some embodiments, a radical-based pre-clean step, a buffer layer formation step, and a dielectric capping layer deposition step may be performed in a single processing chamber, such as in processing chamber 100. Advantageously, performing the pre-clean step, buffer layer formation step, and dielectric capping layer deposition step in a single chamber allows for improved throughput and improved adhesion between the dielectric capping layer(s) 230 and metal interconnects 220, for example, due to a reduction in substrate contamination that may occur after the pre-clean step and before the dielectric capping layer deposition step. In other embodiments, one or more of these steps may be performed in processing chamber 100 (or a similar chamber) and one or more of these steps may be performed in a separate processing chamber.

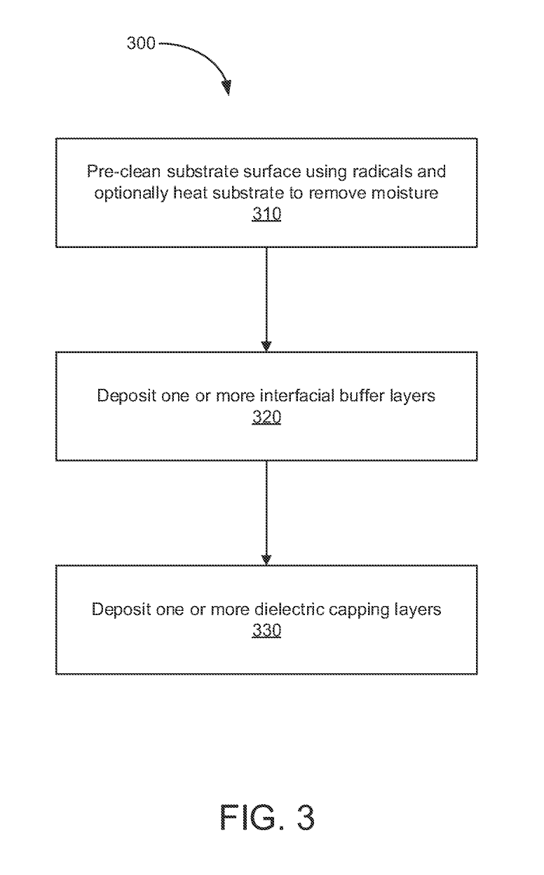

FIG. 3 is a flow diagram of a representative method 300 of processing a substrate 210. The method 300 for processing the substrate 210 has multiple steps. The steps can be carried out in any order or simultaneously (except where the context excludes that possibility), and the method 300 can include one or more other steps which are carried out before any of the defined steps, between two of the defined steps, or after all the defined steps (except where the context excludes that possibility). Not all embodiments include all the steps.

In general, the method 300 includes step 310. At step 310, the substrate 210 and/or a surface of the metal interconnects 220 is pre-cleaned using radicals generated via the radical source 150. In some embodiments, radical-forming gases are introduced into the radical source 150 to generate hydrogen radicals and/or NH radicals. The radical-forming gases used to form hydrogen radicals may include, for example, H₂, a mixture of H₂ and NH₃, a mixture of H₂ and O₂, a mixture of H₂ and H₂O, and/or a mixture of H₂ and N₂. The radical-forming gases used to form NH radicals may include, for example, NH₃ and/or a mixture of NH₃ and H₂. Optionally, carrier gases may be included along with radical-forming gases. Representative carrier gases include argon and helium.

Radicals generated from the radical-forming gases are then introduced into the radical cavity 135, through the gas distribution plate 170, and into the processing zone 141. In the processing zone 141, the hydrogen and/or NH radicals may remove native oxide (e.g., CuOₓ) from the surface of the metal interconnects 220 in order to improve adhesion between the metal interconnects 220 and one or more dielectric capping layers 230 that are subsequently deposited onto the metal interconnects 220. Adhesion may be further improved by heating the substrate 210 during the pre-clean step 310 to remove moisture from one or more layers disposed on the substrate 210. Moreover, providing radicals into the processing zone 141 using the techniques described above allow native oxide to be removed in a mild and low-damage environment, reducing damage to low-dielectric layers (e.g., SiOC layers) disposed on the substrate 210.

Next, at step 320, one or more optional interfacial buffer layers 232 may be deposited onto the metal interconnects 220 prior to depositing the dielectric capping layer(s) 230. In some embodiments, buffer layer(s) 232 may be deposited by injecting a precursor directly into the processing zone 141, such as via the second gas inlet(s) 174. In other embodiments, the precursor(s) used to form the buffer layer(s) 232 may be introduced to into the processing chamber 100 through the first gas inlet(s) 154. In such embodiments, the precursor(s) may be modified by the radical source 150 and/or injected directly into the processing zone 141 via the radical conduit 157 without modification. The precursor(s) may be exposed to radicals, such as nitrogen radicals and/or NH radicals, in the processing zone 141 to deposit the buffer layer(s) 232. Optionally, carrier gases may be included along with the precursor(s). Representative carrier gases include argon and helium. Representative precursors include silicon-containing precursor gases, such as silane and trisilylamine (TSA). In some embodiments, the buffer layer(s) 232 deposited at step 320 may include one or more SiN layers, CuSiₓ (e.g., deposited via a trisilylamine soaking process), and/or cobalt (Co) (e.g., deposited via selective CVD). The buffer layer(s) may have a thickness of between about 10 Å and about 1000 Å, such as between about 10 Å and about 100 Å. In other embodiments, other types of buffer layers 232 may be formed using other radical-forming gases and/or other precursors, such as the radical-forming gases and precursors described below.

At step 330, one or more dielectric capping layers 230 are deposited on the optional interfacial buffer layer(s) 232. In various embodiments, at step 330, at least one radical-forming gas and one or more optional carrier gases are introduced into the radical source 150 of the processing chamber 100 from the first gas inlet(s) 154. At least one precursor gas is introduced into the processing zone 141 from the second gas inlet(s) 174. Radicals are generated in the radical source 150 and are introduced into the processing zone 141 to deposit one or more dielectric capping layers 230. The radicals are supplied until layer(s) 230 of the desired thickness(es) are obtained. The dielectric capping layer(s) 230 may have a thickness of between about 10 Å and about 1000 Å, such as between about 50 Å and about 500 Å.

The resulting dielectric capping layer(s) 230 may include, but are not limited to, silicon-containing dielectric films and/or aluminum-containing dielectric films. For example, layers may be deposited that are composed of SiC, SiCN, SiO₂, SiOCN, SiOC, SiON and SiN. The composition of the layers depends on the composition of the precursor gases. SiC layers may be deposited, for example, by using (dimethylsilyl)(trimethylsilyl)methane, hexamethyldisilane, and/or trimethylsilane. SiCN layers may be deposited, for example, by using tris(dimethylamino)silane, bis(dimethylamino)methylsilane, and/or (dimethylamino)dimethylsilane. SiO₂ may be deposited, for example, by using disiloxane. SiOCN layers can be formed, for example, by using tris(dimethylamino)silane, bis(dimethylamino)methylsilane, and/or (dimethylamino)dimethylsilane. SiON layers can be formed, for example, by using disiloxane or trisilylamine. SiN layers may be deposited, for example, by using trisilylamine. The resulting layers may be amorphous.

In the same or other embodiments, layers may be deposited that are composed of AlN, AlO, and AlON. The composition of the layers depends on the composition of the precursor gases. AlN, AlO, and AlON layers may be deposited, for example, by using trimethylaluminum (TMA) and/or process gases such as Ar, NH₃, H₂, O₂ and/or H₂O. The resulting layers may be amorphous. Additionally, any of the silicon-containing layers described above may be combined with any of the aluminum-containing layers described above to form the dielectric capping layer(s) 230 and/or the layers may be deposited using both silicon-containing precursors and aluminum-containing precursors. For example, in some embodiments, the dielectric capping layer(s) 230 may include AlN, AlON, AlO, SiCN, SiCON, SiN, AlSiCN, and/or AlSiN layers. In the same or other embodiments, the dielectric capping layer(s) 230 may include composite layers, such as AlN/SiCN, AlN/SiN, SiN/SiON, and/or SiN/SiCON layers.

In another embodiment, a material containing Si—H, C—H, and/or N—H bonds is placed inside a processing chamber, such as processing chamber 100. Thereafter, the material may be treated with radicals, such as hydrogen radicals, generated substantially as described above, in order to reduce the number of Si—H, C—H, and N—H bonds.

Radical-forming gases that may be introduced into the radical source 150 include H₂, H₂O, N₂, O₂, NH₃, and mixtures thereof. For example, the radical-forming gas may be a mixture of H₂ and N₂. Alternatively, the radical-forming gas may be a mixture of H₂ and O₂. In another embodiment, the radical-forming gas may be a mixture of H₂, N₂, and O₂. In other embodiments, the mixture of radical-forming gases may comprise NH₃ and H₂. The radicals may include hydrogen radicals, hydroxyl radicals, nitrogen radicals, NH radicals, oxygen radicals, and mixtures thereof. Hydrogen radicals can be generated, for example, from H₂, a mixture of H₂ and NH₃, a mixture of H₂ and O₂, a mixture of H₂ and H₂O, and/or a mixture of H₂ and N₂. Hydroxyl radicals can be generated, for example, from H₂O, a mixture of O₂ and H₂, and/or a mixture of H₂ and H₂O. Nitrogen radicals can be generated, for example, from a mixture of H₂ and N₂. Nitrogen and NH radicals may be generated, for example, from NH₃ and/or a mixture of NH₃ and H₂. Oxygen radicals can be generated, for example, from O₂ and/or a mixture of H₂ and O₂. Optionally, carrier gases may be included along with radical-forming gases. Representative carrier gases include argon and helium.

The one or more precursor gases that may be introduced into the processing zone 141 include one or more silicon-containing gases. For example, the one or more precursor gases may include organosilicon, tetraalkyl orthosilicate gases, or disiloxane. Organosilicon gases include gases of organic compounds having at least one carbon-silicon bond. Tetraalkyl orthosilicate gases include gases consisting of four alkyl groups attached to an SiO₄⁴⁻ ion. More particularly, the one or more precursor gases may include (dimethylsilyl)(trimethylsilyl)methane ((Me)₃SiCH₂SiH(Me)₂); hexamethyldisilane ((Me)₃SiSi(Me)₃); trimethylsilane ((Me)₃SiH); tetramethylsilane ((Me)₄Si); tetraethoxysilane ((EtO)₄Si); tetramethoxysilane ((MeO)₄Si); tetrakis-(trimethylsilyl)silane ((Me₃Si)₄Si); (dimethylamino)dimethylsilane ((Me₂N)SiHMe₂); dimethyldiethoxysilane ((EtO)₂Si(Me)₂); dimethyldimethoxysilane ((MeO)₂Si(Me)₂); methyltrimethoxysilane ((MeO)₃Si(Me)); dimethoxytetramethyl-disiloxane (((Me)₂Si(OMe))₂O); tris(dimethylamino)silane ((Me₂N)₃SiH); bis(dimethylamino)methylsilane ((Me₂N)₂CH₃SiH); disiloxane ((SiH₃)₂O); and combinations thereof.

The conditions of the processing chamber 100 during the pre-clean step 310, optional interfacial layer deposition step 320, and/or dielectric capping layer deposition step 330 may be as follows. The temperature of processing chamber 100 may be maintained between about 100° C. and 800° C., such as between about 100° C. and 500° C., or between about 100° C. and 300° C. The pressure of the processing chamber 100 may be maintained between about 10 mTorr and about 20 Torr, such as between about 10 mTorr and about 10 Torr, or between about 0.5 Torr and about 8 Torr. Radical-forming gases may be introduced into the radical source 150 at a flow rate ranging from about 1 sccm to about 50,000 sccm for a 300 mm substrate. If one or more carrier gases are used, the flow rate of the carrier gas(es) may range from about 1 sccm to about 50,000 sccm for a 300 mm substrate. Radicals may be generated by the radical source 150. For example, if the radical source 150 is a capacitively coupled remote plasma source, the radicals may be generated from an RF power of between about 50 W and about 10,000 W for a 300 mm substrate, such as an RF power from about 2,000 W to about 15,000 W. Additionally, during the optional interfacial layer deposition step 320 and/or the dielectric capping layer deposition step 330, the silicon-precursor gas(es) may be introduced into the processing zone 141 at a flow rate ranging from about 0.1 sccm to about 10,000 sccm for a 300 mm substrate.

In a representative example of the method 300 described above, after pre-cleaning the substrate 210 surface, a SiN layer (e.g., interfacial buffer layer 232) may be deposited onto Cu interconnects (e.g., interconnects 220) to improve adhesion between the Cu interconnects and the dielectric capping layer(s) 230. Then, one or more SiCN and/or SiCON layers (e.g., dielectric capping layer(s) 330) may be deposited on top of the SiN layer to further improve the Cu diffusion-inhibiting performance, increase the dielectric breakdown voltage, and/or reduce the leakage current.

To perform deposition of the SiCN and/or SiCON layers on a 300 mm substrate using processing chamber 100, trisilylamine may be introduced into the processing zone 141 at a flow rate of 30 sccm. The radical-forming gases introduced into the radical source 150 include hydrogen and ammonia, which are introduced at flow rates of 5000 sccm and 500 sccm, respectively. Argon is introduced into the radical source 150 as a carrier gas at a flow rate of 5000 sccm. The temperature and pressure of the processing chamber 100 are 200° C. and 1 Torr, respectively. The radical source 150 is a capacitively coupled remote plasma source, and the radicals may be generated from an RF power of 10,000 W. The spacing is 1000 mil. Deposition is carried out for 60 seconds, and the resulting dielectric layer has a thickness of 1000 Å.

In summary, a pre-clean step, interfacial buffer layer deposition step, and dielectric capping layer deposition step may be performed in a manner that reduces the likelihood of damage to one or more substrate layers (e.g., low-dielectric layers). Additionally, adhesion between metal interconnects and the dielectric capping layers may be improved. The pre-clean step, interfacial buffer layer deposition step, and dielectric capping layer deposition step may be performed in a single processing chamber, improving processing throughput and decreasing contamination of substrate layers that may otherwise occur while transferring the substrate between multiple conventional processing chambers. Further, as compared to layers formed using conventional methods, the dielectric layers formed according to the methods disclosed herein exhibit significantly fewer defects, significantly lower shrinkage and significantly better etch selectivity, mechanical stability, and thermal stability.

While the foregoing is directed to embodiments of the present invention, other and further embodiments of the invention may be devised without departing from the basic scope thereof, and the scope thereof is determined by the claims that follow.

What is claimed is:

1. A method of processing a substrate, comprising:
positioning the substrate within a processing zone of a processing chamber;
removing an oxide layer from a surface of the substrate by introducing first radicals into the processing zone;
after removing the oxide layer, introducing at least one first precursor gas into the processing zone; and
depositing at least one dielectric layer onto the surface by exposing the at least one first precursor gas to second radicals,
wherein, after positioning the substrate within the processing zone, the substrate is not removed from the processing chamber until each of removing the oxide layer and depositing the at least one dielectric layer is performed.

2. The method of claim 1, wherein the at least one first precursor gas comprises at least one of a silicon-containing precursor gas and an aluminum-containing precursor gas.

3. The method of claim 1, wherein the at least one first precursor gas comprises at least one of an organosilicon gas, a tetraalkyl orthosilicate gas, disiloxane, and trimethylaluminum (TMA).

4. The method of claim 1, further comprising, after removing the oxide layer and before depositing the at least one dielectric layer:
introducing at least one second precursor gas into the processing zone; and
depositing at least one buffer layer onto the surface by exposing the at least one second precursor gas to third radicals.

5. The method of claim 4, wherein the at least one second precursor gas comprises at least one of silane and trisilylamine.

6. The method of claim 4, wherein the third radicals comprise at least one of nitrogen radicals and NH radicals.

7. The method of claim 4, wherein the at least one buffer layer comprises at least one of SiN, CuSiₓ, and Co.

8. The method of claim 1, wherein the first radicals comprise at least one of hydrogen radicals and NH radicals.

9. The method of claim 1, further comprising removing moisture from the surface of the substrate by heating the substrate within the processing chamber before depositing the at least one dielectric layer.

10. The method of claim 1, wherein the at least one first precursor gas is selected from the group consisting of (dimethylsilyl)(trimethylsilyl)methane, hexamethyldisilane, trimethylsilane, tetramethylsilane, tetraethoxysilane, tetramethoxysilane, tetrakis(trimethylsilyl)silane, (dimethylamino)dimethylsilane, dimethyldiethoxysilane, dimethyldimethoxysilane, methyltrimethoxysilane, dimethoxytetramethyldisiloxane, tris(dimethylamino)silane, bis(dimethylamino)methylsilane, and disiloxane.

11. The method of claim 1, wherein the surface of the substrate comprises a metal interconnect.

12. The method of claim 11, wherein the metal interconnect comprises copper, and the oxide layer comprises a copper oxide.

13. The method of claim 1, wherein the at least one dielectric layer comprises at least one of AlN, AlON, AlO, SiCN, SiCON, SiN, AlSiCN, and AlSiN.

14. The method of claim 1, wherein the first radicals and second radicals are generated in a remote capacitively coupled plasma source, a remote inductively coupled plasma source, or a HW-CVD chamber.

15. A method of processing a substrate, comprising:
positioning the substrate within a processing zone of a processing chamber;
removing an oxide layer from a surface of the substrate by introducing first radicals into the processing zone;
after removing the oxide layer, introducing one or more precursor gases into the processing zone;
depositing at least one buffer layer onto the surface using the one or more precursor gases;
after depositing the at least one buffer layer, introducing a silicon-containing precursor gas into the processing zone; and
depositing at least one of a SiCN layer and a SiCON layer onto the at least one buffer layer by exposing the silicon-containing precursor gas to second radicals.

16. The method of claim 15, wherein, after positioning the substrate within the processing zone, the substrate is not removed from the processing chamber until each of removing the oxide layer, depositing the at least one buffer layer, and depositing the at least one of the SiCN layer and the SiCON layer is performed.

17. The method of claim 15, wherein the at least one buffer layer comprises at least one of SiN, CuSiₓ, and Co.

18. The method of claim 15, wherein the silicon-containing precursor gas comprises at least one of an organosilicon gas, a tetraalkyl orthosilicate gas, and disiloxane.

19. The method of claim 15, wherein the first radicals and second radicals are generated in a remote capacitively coupled plasma source, a remote inductively coupled plasma source, or a HW-CVD chamber.

20. A method of processing a substrate, comprising:
positioning the substrate within a processing zone of a processing chamber;
removing an oxide layer from a surface of the substrate by introducing first radicals into the processing zone;
after removing the oxide layer, introducing one or more first precursor gases into the processing zone;
depositing at least one buffer layer onto the surface using the one or more first precursor gases;
after depositing the at least one buffer layer, introducing one or more second precursor gases into the processing zone; and
depositing at least one dielectric layer onto the at least one buffer layer by exposing the one or more second precursor gases to second radicals,
wherein, after positioning the substrate within the processing zone, the substrate is not removed from the processing chamber until each of removing the oxide layer, depositing the at least one buffer layer, and depositing the at least one dielectric layer is performed.
